(19) United States
(12) Patent Application Publication
(10) Pub. No.: US 2023/0075993 A1
(43) Pub. Date: Mar. 9, 2023

(54) SEMICONDUCTOR MEMORY DEVICE

(71) Applicant: Kioxia Corporation, Tokyo (JP)

(72) Inventors: Koichi SAKATA, Yokkaichi (JP); Shinya ARAI, Yokkaichi (JP); Susumu HASHIMOTO, Yokkaichi (JP); Akira MINO, Yokkaichi (JP); Shunsuke OKADA, Suzuka (JP); Keisuke NAKATSUKA, Kobe (JP)

(73) Assignee: Kioxia Corporation, Tokyo (JP)

(21) Appl. No.: 17/643,263

(22) Filed: Dec. 8, 2021

(30) Foreign Application Priority Data
Sep. 6, 2021 (JP) 2021-144829

(51) Int. Cl. H01L 27/11582; H01L 25/065; H01L 25/18; H01L 23/00; H01L 27/11556

(52) U.S. Cl. CPC H01L 27/11582; H01L 25/0657; H01L 25/18; H01L 24/08; H01L 27/11556; H01L 2224/08145; H01L 2924/1431; H01L 2924/14511

(57) ABSTRACT

According to one embodiment, a semiconductor memory device comprises a substrate, a first conductive layer, and a second conductive layer arranged in this order in a first direction and separated from each other, a first semiconductor film extending in the first direction, intersecting the first conductive layer, and being in contact with the second conductive layer, and a first charge storage film arranged between the first semiconductor film and the first conductive layer, and being in contact with the second conductive layer, wherein the first semiconductor film includes a first portion formed of an n-type semiconductor at approximately a same height as the first conductive layer.

### CROSS-REFERENCE TO RELATED APPLICATIONS

This application is based upon and claims the benefit of priority from Japanese Patent Application No. 2021-144829, filed Sep. 6, 2021, the entire contents of which are incorporated herein by reference.

### FIELD

Embodiments described herein relate generally to a semiconductor memory device.

### BACKGROUND

A NAND flash memory has been known as a semiconductor memory device capable of storing data in a nonvolatile manner. For semiconductor memory devices such as a NAND flash memory, a three-dimensional memory structure is adopted in order to achieve high integration and high capacity.

### BRIEF DESCRIPTION OF THE DRAWINGS

FIG. 1 is a block diagram showing an exemplary configuration of a memory system including a semiconductor memory device according to the present embodiment.

FIG. 2 is a circuit diagram showing an exemplary circuit configuration of a memory cell array in the semiconductor memory device according to the embodiment.

FIG. 3 is a cross-sectional view of the memory cell array of the semiconductor memory device according to the embodiment.

FIG. 4 is a conceptual diagram showing a distribution of impurity concentration in the semiconductor film of a memory pillar in the semiconductor memory device according to the embodiment.

FIG. 5 is a planar layout showing an exemplary semiconductor memory device according to the second embodiment.

FIG. 6 is a cross section of the semiconductor memory device of FIG. 5, taken along line VI-VI.

FIG. 7 is a flowchart showing an exemplary method for manufacturing the semiconductor memory device according to the embodiment.

FIG. 8 is a cross-sectional view showing an exemplary method for manufacturing the memory cell array of the semiconductor memory device according to the embodiment.

FIG. 9 is a cross-sectional view showing the exemplary method for manufacturing the memory cell array of the semiconductor memory device according to the embodiment.

FIG. 10 is a cross-sectional view showing the exemplary method for manufacturing the memory cell array of the semiconductor memory device according to the embodiment.

FIG. 11 is a cross-sectional view showing the exemplary method for manufacturing the memory cell array of the semiconductor memory device according to the embodiment.

FIG. 12 is a cross-sectional view showing the exemplary method for manufacturing the memory cell array of the semiconductor memory device according to the embodiment.

FIG. 13 is a cross-sectional view showing the exemplary method for manufacturing the memory cell array of the semiconductor memory device according to the embodiment.

FIG. 14 is a cross-sectional view of a memory cell array of a semiconductor memory device according to the first modification example.

FIG. 15 is a conceptual diagram showing a distribution of impurity concentration in the semiconductor films of a memory pillar in the semiconductor memory device according to the first modification example.

FIG. 16 is a cross-sectional view of a memory cell array of a semiconductor memory device according to the second modification example.

FIG. 17 is a cross-sectional view showing an exemplary method for manufacturing the memory cell array of the semiconductor memory device according to the second modification example.

FIG. 18 is a cross-sectional view showing an exemplary method for manufacturing the memory cell array of the semiconductor memory device according to the second modification example.

FIG. 19 is a cross-sectional view of a memory cell array of a semiconductor memory device according to the third modification example.

### DETAILED DESCRIPTION

In general, according to one embodiment, a semiconductor memory device comprises a substrate, a first conductive layer, and a second conductive layer arranged in this order in a first direction and separated from each other, a first semiconductor film extending in the first direction, intersecting the first conductive layer, and being in contact with the second conductive layer, and a first charge storage film arranged between the first semiconductor film and the first conductive layer, and being in contact with the second conductive layer, wherein the first semiconductor film includes a first portion formed of an n-type semiconductor at approximately a same height as the first conductive layer.

The embodiments will be explained below by referring to the drawings. The dimensions and ratios in the drawings are not always the same as the actual ones.

In the following explanation, components having basically the same functions and configurations will be referred to by the same reference numerals. If components having substantially the same configurations need to be differentiated from each other, distinguishing numerals or characters may be attached to the end of the reference numerals.

### 1. Embodiment

### 1.1 Configuration

### 1.1.1 Memory System

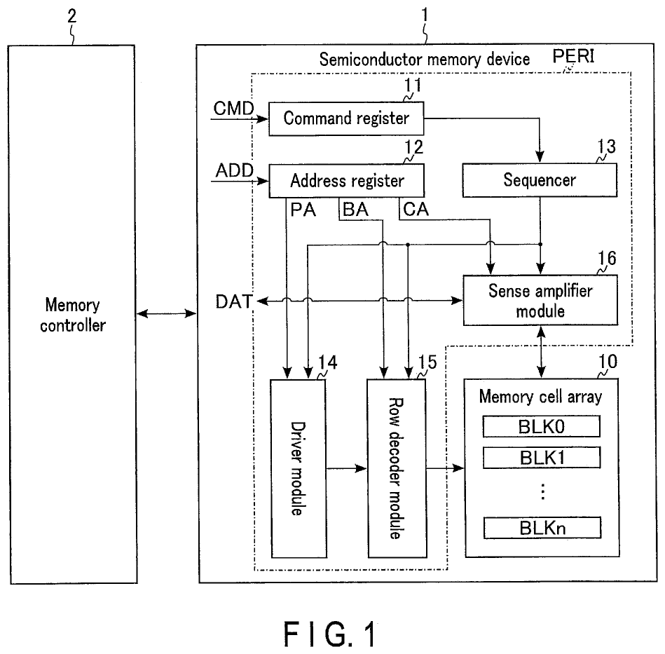

FIG. 1 is a block diagram showing an exemplary configuration of a memory system including a semiconductor memory device according to the present embodiment. The memory system is a storage device configured to be coupled to an external host device, which is not shown. Examples of a memory system include memory cards such as an SD™ card, a universal flash storage (UFS), and a solid state drive (SSD).

The memory system includes a semiconductor memory device 1 and a memory controller 2.

The semiconductor memory device 1 is a memory that stores data in a nonvolatile manner. The semiconductor memory device 1 is, for example, a NAND-type flash memory.

The memory controller 2 is composed of an integrated circuit such as a system-on-a-chip (SoC). In response to a request from the host device, the memory controller 2 controls the semiconductor memory device 1. In particular, the memory controller 2 writes in the semiconductor memory device 1, for example, the data requested by the host device to be written. The memory controller 2 also reads from the semiconductor memory device 1 the data requested by the host device to be read, and transmits the data to the host device.

Communications between the semiconductor memory device 1 and the memory controller 2 are in conformity with, for example, a single data rate (SDR) interface, a toggle double data rate (DDR) interface, or an open NAND flash interface (ONFI).

### 1.1.2 Semiconductor Memory Device

The block diagram of FIG. 1 will still be referred to in the explanation of the internal configuration of the semiconductor memory device according to the present embodiment. The semiconductor memory device 1 includes, for example, a memory cell array 10 and a peripheral circuit PERI. The peripheral circuit PERI includes a command register 11, an address register 12, a sequencer 13, a driver module 14, a row decoder module 15, and a sense amplifier module 16.

The memory cell array 10 includes a plurality of blocks BLK0 to BLKn (where n is an integer larger than or equal to 1). A block BLK is a set of memory cell transistors capable of storing data in a nonvolatile manner. A block BLK may serve as a data erasable unit. The memory cell array 10 is provided with a plurality of bit lines and word lines. One memory cell transistor is associated, for example, with one bit line and one word line.

The command register 11 stores commands CMD that the semiconductor memory device 1 receives from the memory controller 2. The commands CMD include, for example, instructions to instruct the sequencer 13 to implement a read operation, a write operation, an erase operation, and the like.

The address register 12 stores address information ADD that the semiconductor memory device 1 receives from the memory controller 2. The address information ADD includes, for example, a page address PA, a block address BA, and a column address CA. The page address PA, block address BA, and column address CA may be used for selection of a word line, a block BLK, and a bit line.

The sequencer 13 controls the overall operation of the semiconductor memory device 1. For instance, the sequencer 13 may control the driver module 14, row decoder module 15, and sense amplifier module 16 based on a command CMD stored in the command register 11 to implement a read operation, a write operation, and an erase operation.

The driver module 14 generates a voltage to be used in the read operation, write operation, erase operation, and the like. Then, the driver module 14 applies, based on the page address PA stored in the address register 12, the generated voltage to a signal line corresponding to the selected word line.

The row decoder module 15 selects, based on the block address BA stored in the address register 12, the corresponding one of the blocks BLK in the memory cell array 10. Then, the row decoder module 15 transfers the voltage applied to the signal line corresponding to the selected word line, to this selected word line in the selected block BLK.

In a write operation, the sense amplifier module 16 transfers the write data received from the memory controller 2 to the memory cell array 10. In a read operation, the sense amplifier module 16 determines the data stored in a memory cell transistor based on the voltage of the bit line. The sense amplifier module 16 transfers the result of the determination as read data DAT to the memory controller 2.

### 1.1.3 Circuit Configuration of Memory Cell Array

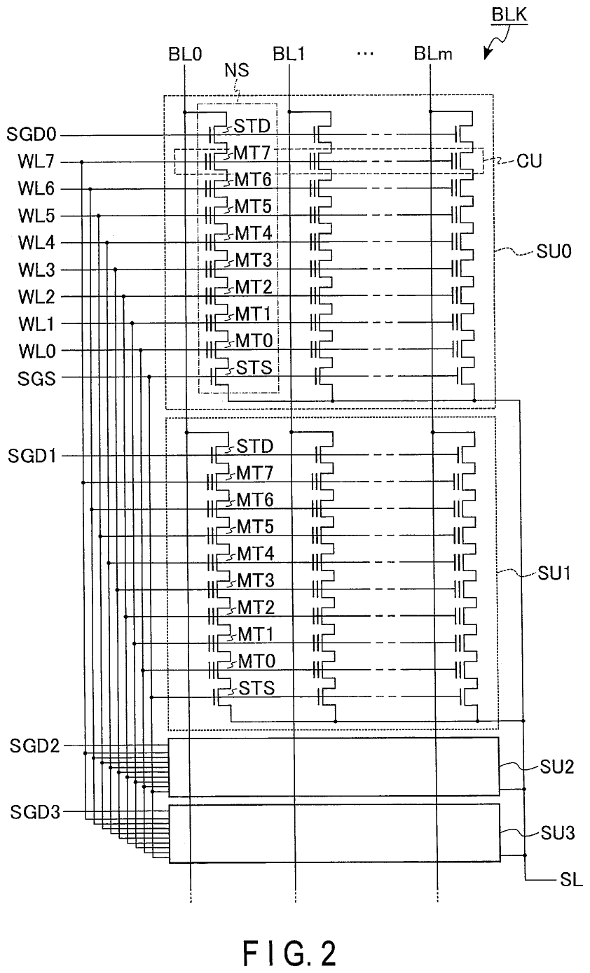

FIG. 2 is a circuit diagram showing an exemplary circuit configuration of a memory cell array in the semiconductor memory device according to the present embodiment. FIG. 2 shows one of the blocks BLK in the memory cell array 10. In the example of FIG. 2, a block BLK contains four string units SU0 to SU3.

Each of the string units SU includes a plurality of NAND strings NS, each associated with one of bit lines BL0 to BLm (where m is an integer greater than or equal to 1). Each NAND string NS includes, for example, memory cell transistors MT0 to MT7, and select transistors STD and STS. Each of the memory cell transistors MT0 to MT7 includes a control gate and a charge storage layer, and stores data in a nonvolatile manner. Each of the select transistors STD and STS is used for selection of a string unit SU in various operations. In the following explanation, the memory cell transistors MT0 to MT7 may be simply referred to as memory cell transistors MT.

In each of the NAND strings NS, the memory cell transistors MT0 to MT7 are coupled in series with each other. The drain of the select transistor STD is coupled to the associated bit line BL, while the source of the select transistor STD is coupled to one end of the memory cell transistors MT0 to MT7 coupled in series. The drain of the select transistor STS is coupled to the other end of the memory cell transistors MT0 to MT7 coupled in series. The source of the select transistor STS is coupled to the source line SL.

Within a block BLK, the control gates of the memory cell transistors MT0 to MT7 are coupled to the corresponding word lines WL0 to WL7. The gates of the select transistors STD in the string units SU0 to SU3 are coupled to the corresponding select gate lines SGD0 to SGD3. On the other hand, the gates of the select transistors STS are coupled in common to the select gate line SGS. This is not a limitation, however, and the gates of the select transistors STS may be coupled to select gate lines SGS0 to SGS3 provided for respective string units SU.

Each of the bit lines BL0 to BLm couples to each other corresponding ones of NAND strings NS included in the string units SU across the blocks BLK. A set of word lines WL0 to WL7 is provided for each block BLK, while the source line SL is shared across a plurality of blocks BLK.

A set of memory cell transistors MT commonly coupled to a word line WL in one string unit SU may be referred to as a cell unit CU. The storage capacity of a cell unit CU including the memory cell transistors MT, which each stores, for example, 1-bit data, is defined as “1-page data”. A cell unit CU may have a storage capacity of 2-page data or more in accordance with the number of bits of the data stored in the memory cell transistor MT.

The circuit configuration of the memory cell array 10 included in the semiconductor memory device 1 according to the present embodiment is not limited to the above. For instance, the number of string units SU in a block BLK may be designed to be any number. The numbers of memory cell transistors MT and select transistors STD and STS in each NAND string NS may also be designed to be any number.

### 1.1.4 Configuration of Memory Cell Array

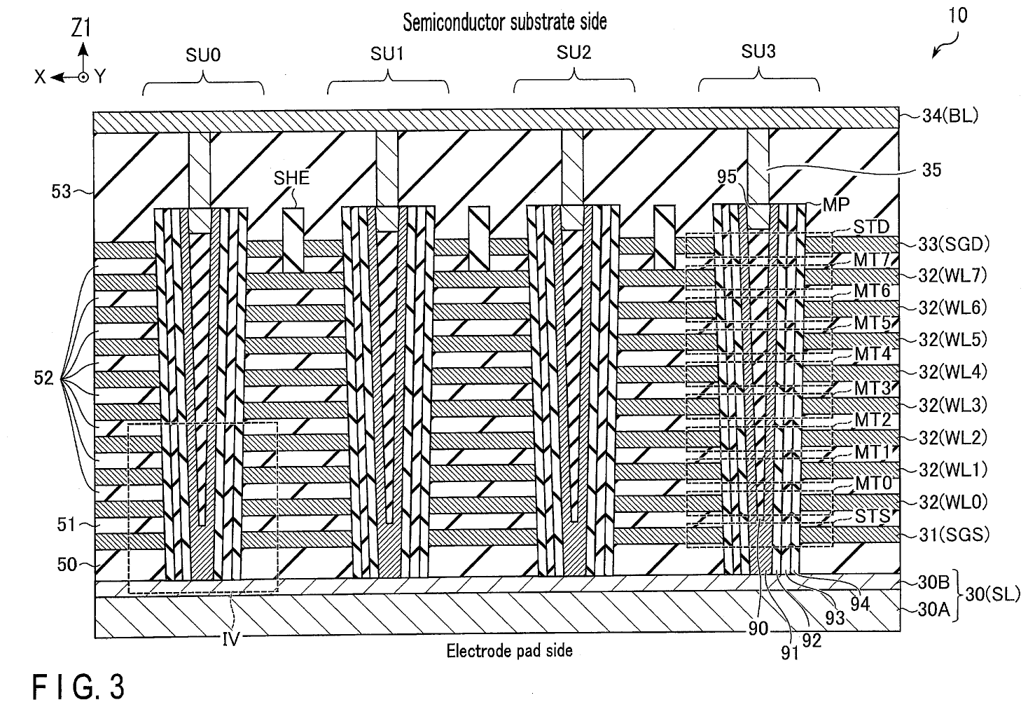

Next, the configuration of the memory cell array 10 will be explained with reference to FIG. 3. In FIG. 3, an exemplary cross-sectional configuration of the memory cell array 10 in the semiconductor memory device 1 according to the present embodiment is illustrated.

In the drawings referred to below, the X direction corresponds to the direction in which the bit lines BL extend, and the Y direction corresponds to the direction in which the word lines WL extend. The Z1 direction corresponds to the direction from the electrode pad of the semiconductor memory device 1 toward the semiconductor substrate, and the Z2 direction corresponds to the direction from the semiconductor substrate of the semiconductor memory device 1 toward the electrode pad. If the Z1 direction and Z2 direction do not need to be differentiated from each other, they will be referred to as the Z direction. In the following explanation, when a given structural component has two surfaces (or two ends) that expand on the XY plane and are aligned along the Z direction, one of the two surfaces (or two ends) on the electrode pad side will be referred to as a first surface (first end), and the other surface on the semiconductor substrate side will be referred to as a second surface (second end).

The memory cell array 10 is arranged between the electrode pad and semiconductor substrate of the semiconductor memory device 1 in the Z direction. The memory cell array 10 includes conductive layers 30 to 35 and a plurality of memory pillars MP (partial configuration illustrated in FIG. 3).

A conductive layer 30 may be formed into a plate expanding along the XY plane. The conductive layer 30 is used as a source line SL. The conductive layer 30 is formed of a metal material. In particular, the conductive layer 30 may include conductive layers 30A and 30B. The conductive layer 30A may be formed into a plate expanding along the XY plane. The conductive layer 30A is formed of tungsten. The conductive layer 30B is stacked on the second surface of the conductive layer 30A. The conductive layer 30B may be formed into a plate expanding along the XY plane. The conductive layer 30B is formed of Ti/TiN (a mixed material of titanium and titanium nitride).

An insulating layer 50 is stacked on the second surface of the conductive layer 30. A conductive layer 31 is stacked on the second surface of the insulating layer 50. A conductive layer 31 may be formed into a plate expanding along the XY plane. The conductive layer 31 is used as a select gate line SGS, and may include tungsten.

An insulating layer 51 is stacked on the second surface of the conductive layer 31. On the second surface of the insulating layer 51 are eight conductive layers 32 and eight insulating layers 52 stacked in the order of a conductive layer 32, an insulating layer 52 . . . , a conductive layer 32, and an insulating layer 52 in the Z1 direction. A conductive layer 32 may be formed into a plate expanding along the XY plane. The eight conductive layers 32 are used as, and referred to as, word lines WL0 to WL7 from the side of the conductive layer 31 in the Z1 direction. The conductive layers 32 may include tungsten.

A conductive layer 33 is stacked on the second surface of the insulating layer 52 closest to the semiconductor substrate. A conductive layer 33 may be formed into a plate expanding along the XY plane. The conductive layer 33 may be used as a select gate line SGD. The conductive layer 33 may include tungsten, and is separated, for example, by members SHE to electrically insulate the string units SU from each other.

An insulating layer 53 is stacked on the second surface of the conductive layer 33. A conductive layer 34 is stacked on the second surface of the insulating layer 53. The conductive layer 34 is arranged to extend along the X direction. The conductive layer 34 functions as a bit line BL.

On the electrode pad side of the conductive layer 34, a plurality of memory pillars MP are arranged to extend along the Z1 direction. The memory pillars MP penetrate the conductive layers 31 to 33.

Each memory pillar MP includes, for example, a core member 90, a semiconductor film 91, a tunnel insulating film 92, a charge storage film 93, a block insulating film 94, and a semiconductor portion 95.

The core member 90 is arranged to extend along the Z1 direction. The first end of the core member 90 is positioned on the semiconductor substrate side with respect to the conductive layer 30. The second end of the core member 90 is positioned on the semiconductor substrate side with respect to the conductive layer 33. The core member 90 may contain silicon oxide.

The semiconductor film 91 is arranged to surround the side surfaces of the core member 90. The first end of the semiconductor film 91 covers the first end of the core member 90 and is in contact with the second surface of the conductive layer 30 (30B). The second end of the semiconductor film 91 is positioned on the semiconductor substrate side with respect to the second end of the core member 90. The semiconductor film 91 may contain polysilicon.

The tunnel insulating film 92 surrounds the side surfaces of the semiconductor film 91. The first end of the tunnel insulating film 92 is at approximately the same height as the first end of the semiconductor film 91. The tunnel insulating film 92 may contain silicon oxide.

The charge storage film 93 surrounds the side surfaces of the tunnel insulating film 92. The first end of the charge storage film 93 is at approximately the same height as the first end of the semiconductor film 91 and the first end of the tunnel insulating film 92. The charge storage film 93 contains an insulator (e.g., silicon nitride) having trap levels, for example.

The block insulating film 94 surrounds the side surfaces of the charge storage film 93. The first end of the block insulating film 94 is at approximately the same height as the first end of the semiconductor film 91, the first end of the tunnel insulating film 92, and the first end of the charge storage film 93. The block insulating film 94 may contain silicon oxide.

The semiconductor portion 95 is arranged to cover the second end of the core member 90. The side surfaces of the semiconductor portion 95 are covered by a portion of the semiconductor film 91 positioned on the semiconductor substrate side with respect to the second end of the core member 90. The second surface of the semiconductor portion 95 is in contact with the first end of the conductive layer 35. The second end of the conductive layer 35 is coupled to the conductive layer 34. The memory pillar MP and conductive layer 34 are electrically coupled to each other by way of the conductive layer 35.

In the above explained configuration of the memory pillar MP, the first end of the semiconductor film 91, the first end of the tunnel insulating film 92, the first end of the charge storage film 93, and the first end of the block insulating film 94 are at approximately the same height, forming the first surface of the memory pillar MP. The first surface of the memory pillar MP is included in the same plane as the first surface of the insulating layer 50.

The intersecting portion of the memory pillar MP and conductive layer 31 functions as a select transistor STS. The intersecting portions of the memory pillar MP and the conductive layers 32 function as memory cell transistors MT. The intersecting portion of the memory pillar MP and the conductive layers 33 functions as a select transistor STD. The semiconductor film 91 functions as a channel for the memory cell transistors MT0 to MT7 and select transistors STS and STD. The charge storage film 93 functions as charge storage layers of the memory cell transistors MT.

### 1.1.5 Impurity Concentration Distribution in Semiconductor Film of Memory Pillar

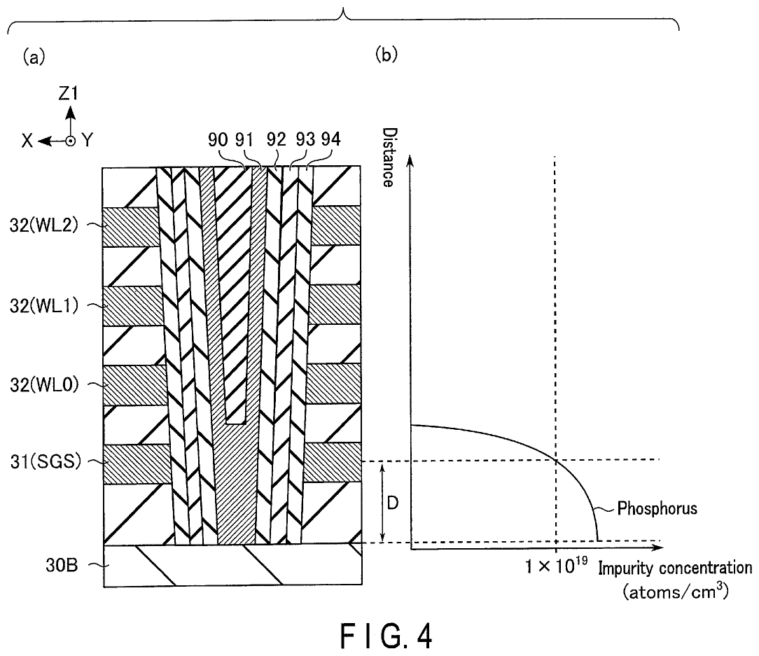

Next, the distribution of impurity concentration in the semiconductor film 91 of a memory pillar MP will be explained with reference to FIG. 4. A conceptual diagram indicating a distribution of impurity concentration in the semiconductor film of a memory pillar in the semiconductor memory device according to the embodiment is shown in FIG. 4, where an enlarged view of the region IV enclosed by the dashed line in FIG. 3 is shown in (a), and the distribution of the concentration of impurities contained in the semiconductor film 91 in the region shown in (a) is indicated in (b).

As indicated in FIG. 4, the first end of the semiconductor film 91 is doped with phosphorous as an impurity. The first end of the semiconductor film 91 therefore exhibits n-type conduction. The impurities for doping the first end of the semiconductor film 91 are not limited to phosphorus. The first end of the semiconductor film 91 may be doped with arsenic.

More specifically, the portion of the semiconductor film 91 within the range of the distance D from the second surface of the conductive layer 30 in the Z1 direction is doped with phosphorus at a concentration of 1×10¹⁹ atoms/cm³ or higher. In the portion of the semiconductor film 91 further away in the Z1 direction from the second surface of the conductive layer 30 than the distance D, the concentration of phosphorus may be lower than 1×10¹⁹ atoms/cm³. The distance D is shorter than the distance from the second surface of the conductive layer 30 to the second surface of the conductive layer 31, and longer than the distance from the second surface of the conductive layer 30 to the first surface of the conductive layer 31.

With such a configuration, the channel of the select transistor STS includes a portion having a phosphorus concentration of 1×10¹⁹ atoms/cm³ or higher. As a result, the select transistor STS can generate a gate-induced drain leakage (GIDL) current in an erase operation of the semiconductor memory device 1. The GIDL current is a current that generates an electron-hole pair. A positive hole of the electron-hole pair generated by the GIDL current is injected into the charge storage film 93 via the channel. The injected positive holes are recombined with electrons that have been injected in a write operation or the like so that the electrons disappear from the charge storage layer of the memory cell transistor MT. This lowers the threshold voltage of the memory cell transistor MT. In other words, the data stored in the memory cell transistor MT is erased.

Furthermore, the channel of the select transistor STS includes a portion having a phosphorus concentration lower than 1×10¹⁹ atoms/cm³. With this portion, the select transistor STS functions as a switch element in various operations.

### 1.1.6 Configuration of Semiconductor Memory Device

An exemplary structure of the semiconductor memory device 1 according to the embodiment will be described below.

### 1.1.6.1 Planar Layout of Semiconductor Memory Device

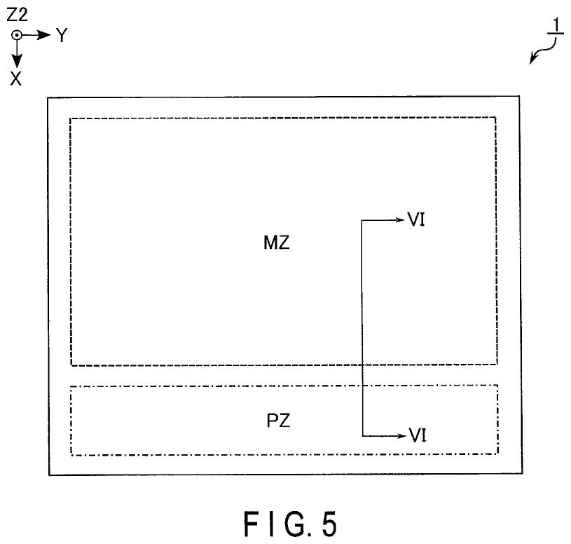

The planar layout of the semiconductor memory device 1 according to the present embodiment will be explained with reference to FIG. 5. An exemplary planar layout of the semiconductor memory device 1 according to the present embodiment is illustrated in FIG. 5.

As illustrated in FIG. 5, the semiconductor memory device 1 may include a memory region MZ and a pad region PZ when viewed on the XY plane. The memory region MZ and pad region PZ are arranged next to each other in the X direction.

The memory region MZ includes a memory cell array 10.

In the pad region PZ, an electrode pad is arranged for connection between the semiconductor memory device 1 and an external device such as the memory controller 2.

### 1.1.6.2 Cross-sectional Configuration of Semiconductor Memory Device

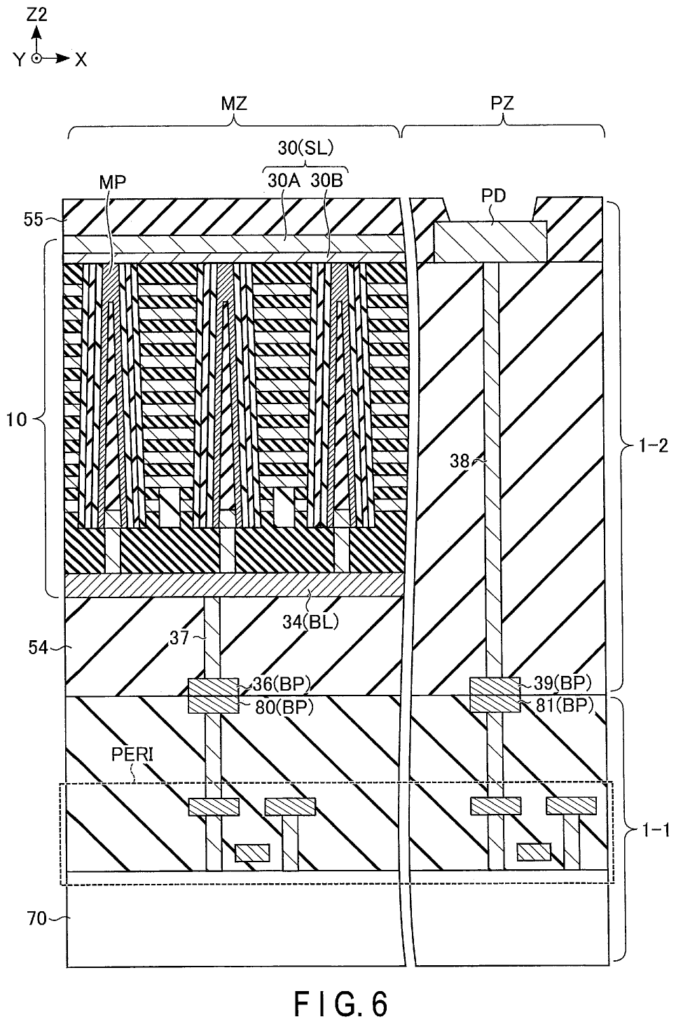

An exemplary configuration of the semiconductor memory device 1 according to the present embodiment will be explained with reference to FIG. 6. An exemplary cross-sectional configuration of the semiconductor memory device 1 is illustrated in FIG. 6.

As illustrated in FIG. 6, the semiconductor memory device 1 has a configuration in which the first surface of a circuit chip 1-1 is adhered to the second surface of a memory chip 1-2. The circuit chip 1-1 includes a semiconductor substrate 70, conductive layers 80 and 81, and a peripheral circuit PERI. The memory chip 1-2 includes conductive layers 36, 37, 38 and 39, insulating layers 54 and 55, a memory cell array 10, and an electrode pad PD.

First, the cross-sectional configuration of the circuit chip 1-1 will be explained.

The semiconductor substrate 70 is arranged at the second end of the circuit chip 1-1. A peripheral circuit PERI is formed on the first surface of the semiconductor substrate 70. In FIG. 6, two transistors are shown as an exemplary structure in the peripheral circuit PERI.

Conductive layers 80 and 81 are coupled to these two transistors in the peripheral circuit PERI. The conductive layers 80 and 81 are provided in the memory region MZ and pad region PZ, respectively. Each of the conductive layers 80 and 81 is arranged in a manner such that the first surface thereof is flush with the first surface of the circuit chip 1-1. The conductive layers 80 and 81 function as connection pads BP to establish an electrical connection between the circuit chip 1-1 and memory chip 1-2.

Next, the cross-sectional configuration of the memory chip 1-2 will be explained.

The conductive layers 36 and 39 are provided in the memory region MZ and pad region PZ, respectively. Each of the conductive layers 36 and 39 is arranged in a manner such that the second surface thereof is flush with the second surface of the memory chip 1-2. The conductive layers 36 and 39 are in contact with the conductive layers 80 and 81, respectively. As a result, the conductive layers 36 and 39 function as connection pads BP to establish an electrical connection between the circuit chip 1-1 and memory chip 1-2.

The conductive layer 36 is coupled to the memory cell array 10 by way of the conductive layer 37. The conductive layer 37 functions as a contact. In the memory cell array 10, the conductive layer 34 is arranged on the semiconductor substrate 70 side, while the conductive layer 30 is arranged on the electrode pad PD side.

The conductive layer 39 is coupled to an electrode pad PD by way of the conductive layer 38. The conductive layer 38 functions as a contact. The contact surface of the conductive layer 38 and electrode pad PD is at approximately the same height as the contact surface of the conductive layer 30 (conductive layer 30B) and the memory pillar MP. This is not a limitation, however, and the contact surface between the conductive layer 38 and electrode pad PD may be positioned further away in the Z2 direction from the semiconductor substrate 70 with respect to the contact surface of the conductive layer 30 and memory pillar MP. In such a configuration, the conductive layer 39 will be coupled to the electrode pad PD by way of the conductive layer 38 and a conductive layer different from conductive layer 38.

The electrode pad PD may be coupled to the substrate or external device with bonding wire, solder balls, metal bumps and the like. The electrode pad PD may contain copper.

The side surfaces of conductive layers 31 to 39 are covered by an insulating layer 54. The insulating layer 54 may contain silicon oxide.

The first surface of the memory cell array 10 and the side surface of the electrode pad PD are covered by an insulating layer 55. The insulating layer 55 is used as a passivation film. The insulating layer 55 may contain silicon oxide.

### 1.2 Manufacturing Method

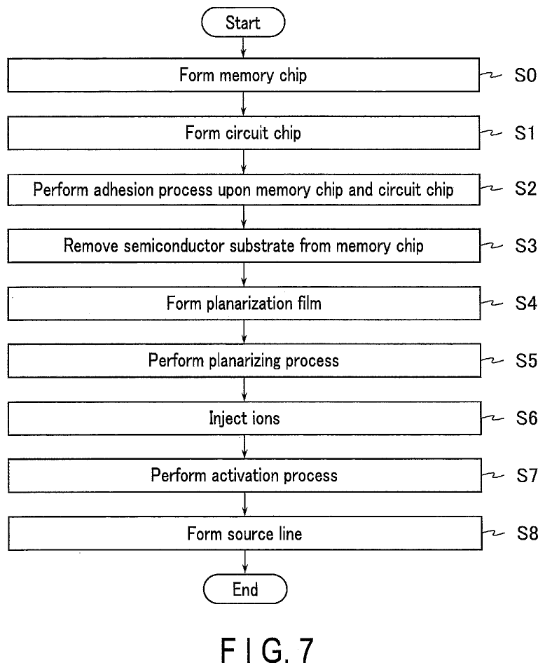

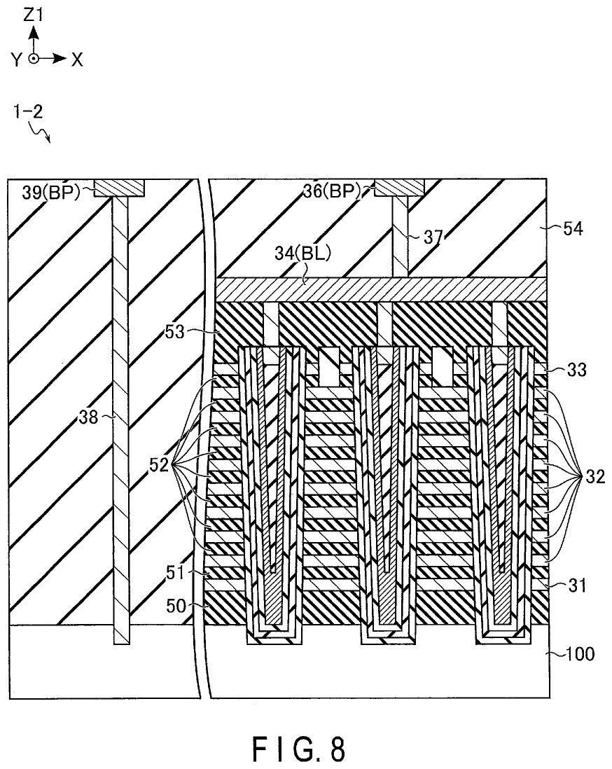

An exemplary process of manufacturing the semiconductor memory device 1 according to the present embodiment will be explained below with reference to FIGS. 7 to 13. FIG. 7 is a flowchart showing the process of manufacturing the semiconductor memory device 1 according to the present embodiment. Each of FIGS. 8 to 13 shows an exemplary cross-sectional configuration of the semiconductor memory device 1 at a step of the manufacturing process of the semiconductor memory device 1 according to the present embodiment. The region illustrated in each of FIGS. 8 to 13 at a step of the manufacturing process corresponds to the region illustrated in FIG. 6.

First, a memory chip 1-2 is formed (S0), as shown in FIG. 8. Specifically, first, a layer-stacked structure including a plurality of sacrificial layers corresponding to the conductive layers 31 to 33 and insulating layers 50 to 53 is formed on the semiconductor substrate 100. Next, in such a layer-stacked structure, a plurality of memory holes (not shown) are formed to correspond to a plurality of memory pillars MP. Each of the memory holes penetrates the layer-stacked structure to reach the semiconductor substrate 100. Then, to fill the memory holes, a block insulating film 94, a charge storage film 93, a tunnel insulating film 92, a semiconductor film 91, and a core member 90 are formed in this order. The core member 90 is partially etched back, and thereafter a semiconductor portion 95 is formed. Then, a slit is formed to divide the sacrificial layers in the layer-stacked structure. Through the formed slit, the sacrificial layers are replaced with conductive layers 31 to 33. Thereafter, conductive layers 34 and 35 are formed. To cover the conductive layer 34, an insulating layer 54 is formed. Holes are formed in the areas of the insulating layer 54 where the conductive layers 37 and 38 will be formed, with a process using lithography, anisotropic etching, and the like. To fill the holes formed in the insulating layer 54, conductive layers 37 and 38 are formed. After the formation of the conductive layers 37 and 38, conductive layers 36 and 39 are formed in contact with the second ends of the conductive layers 37 and 38.

Next, a circuit chip 1-1 is formed (S1). Since the circuit chip 1-1 is formed using a semiconductor substrate 70 that differs from that of the memory chip 1-2, the process of forming the memory chip 1-2 and the process of forming the circuit chip 1-1 may be conducted in parallel.

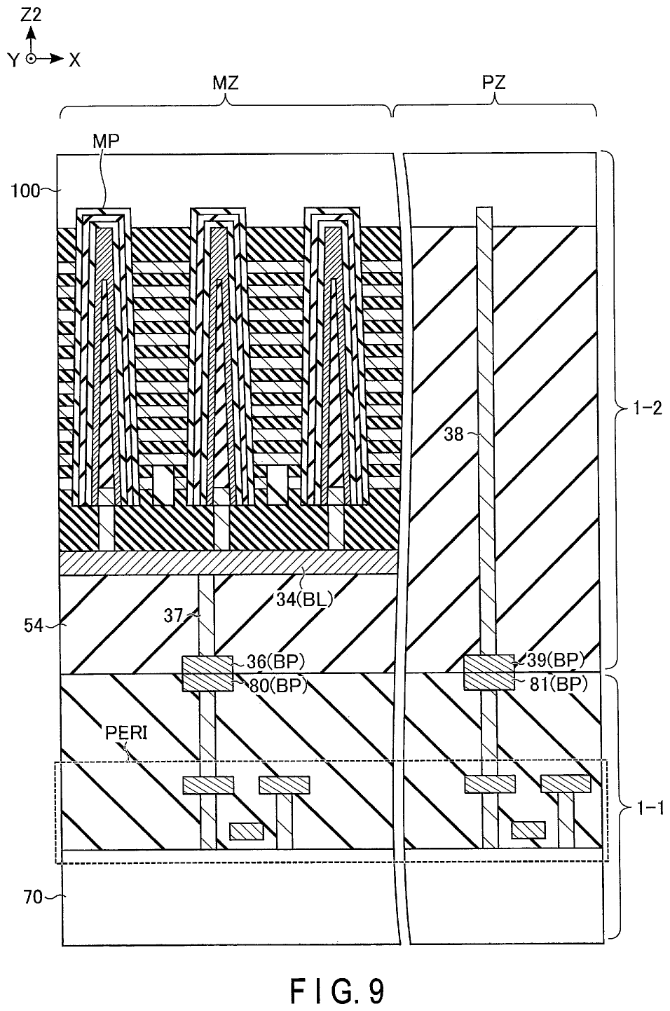

As illustrated in FIG. 9, the memory chip 1-2 is adhered by an adhesion process (S2) to the circuit chip 1-1 formed at step S1. In particular, the conductive layers 36 and 39 exposed at one end of the memory chip 1-2 are positioned to respectively face the conductive layers 80 and 81 exposed at one end of the circuit chip 1-1. The connection pads BP facing each other are bonded to each other through a thermal process.

The semiconductor substrate 100 of the memory chip 1-2 is removed. As a result, the first end of the memory pillar MP and the first end of the conductive layer 38 are exposed on the first surface of the memory chip 1-2 (S3). The removal of the semiconductor substrate 100 may be performed through chemical mechanical polishing (CMP).

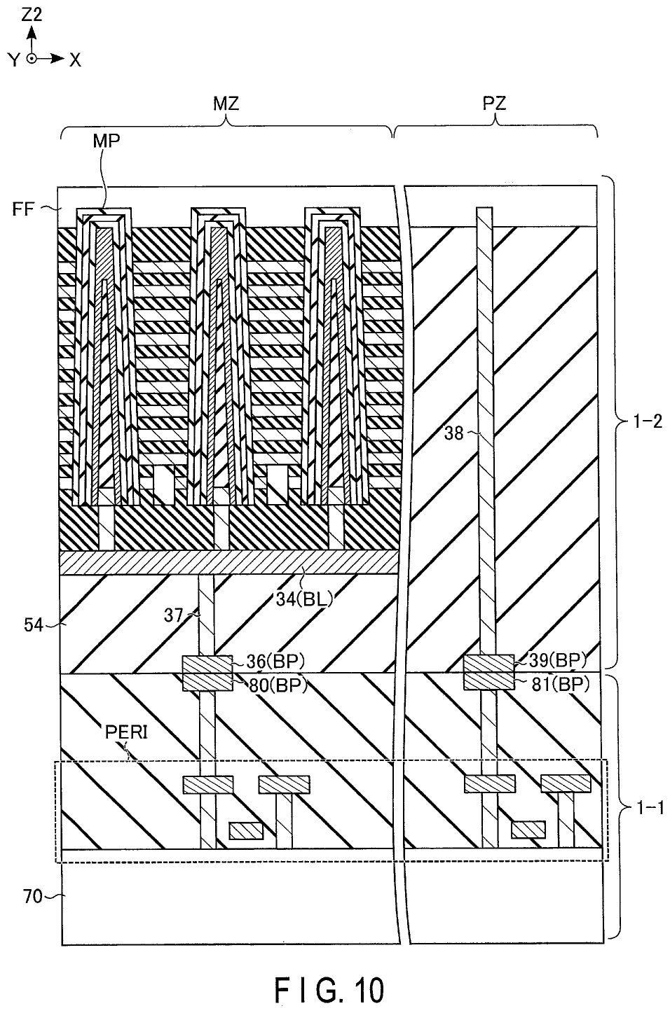

Next, as illustrated in FIG. 10, a planarization film FF is formed on the first surface of the memory chip 1-2 (S4) to cover the first end of the memory pillar MP and the first end of the conductive layer 38 exposed at step S3. The first surface of the planarization film FF is parallel to the first surface of the semiconductor substrate 70. The planarization film FF may be a bottom anti-reflection coating (BARC). The planarization film FF can be anything other than a BARC as long as it can cover the first end of the memory pillar MP and the first end of the conductive layer 38 exposed at step S3, and can form a first surface parallel to the first surface of the semiconductor substrate 70.

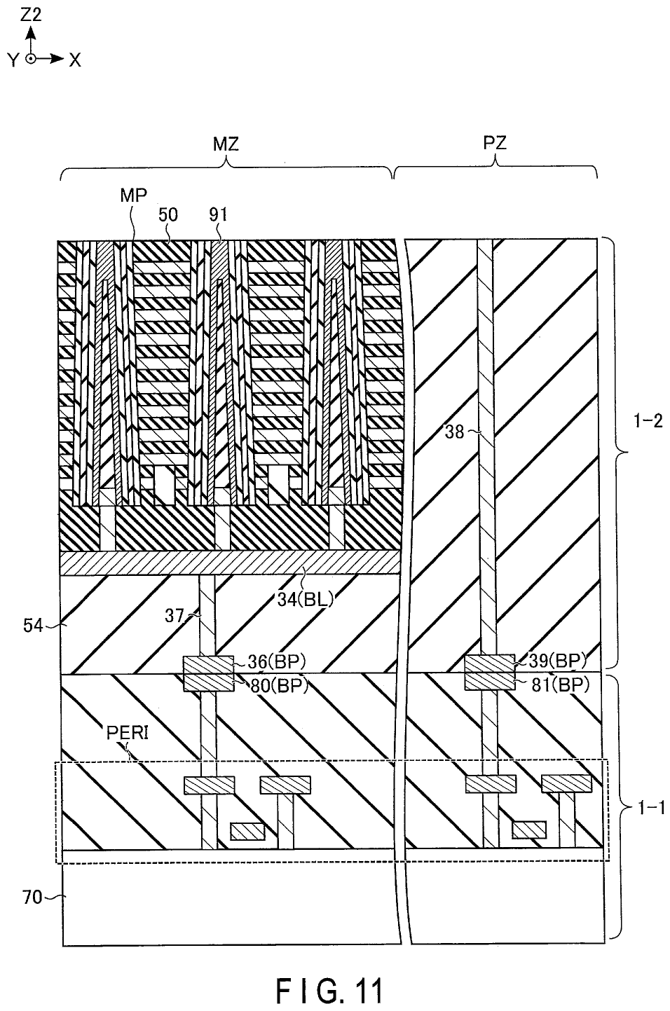

As illustrated in FIG. 11, a planarizing process is implemented on the first end of the memory chip 1-2 (S5). In particular, a portion of the first end of the memory chip 1-2 is removed, for example by reactive ion etching (RIE), by a predetermined thickness so as to become parallel to the semiconductor substrate 70. As a result, the planarization film FF, the first end of the memory pillar MP, the first end of the conductive layer 38, the first end of the insulating layer 50, and the first end of the insulating layer 54 are removed, which brings the first end of the memory pillar MP, the first end of the conductive layer 38, the first end of the insulating layer 50, and the first end of the insulating layer 54 to approximately the same height. Furthermore, the first surface of the semiconductor film 91 in each memory pillar MP is exposed on the first surface of the memory chip 1-2.

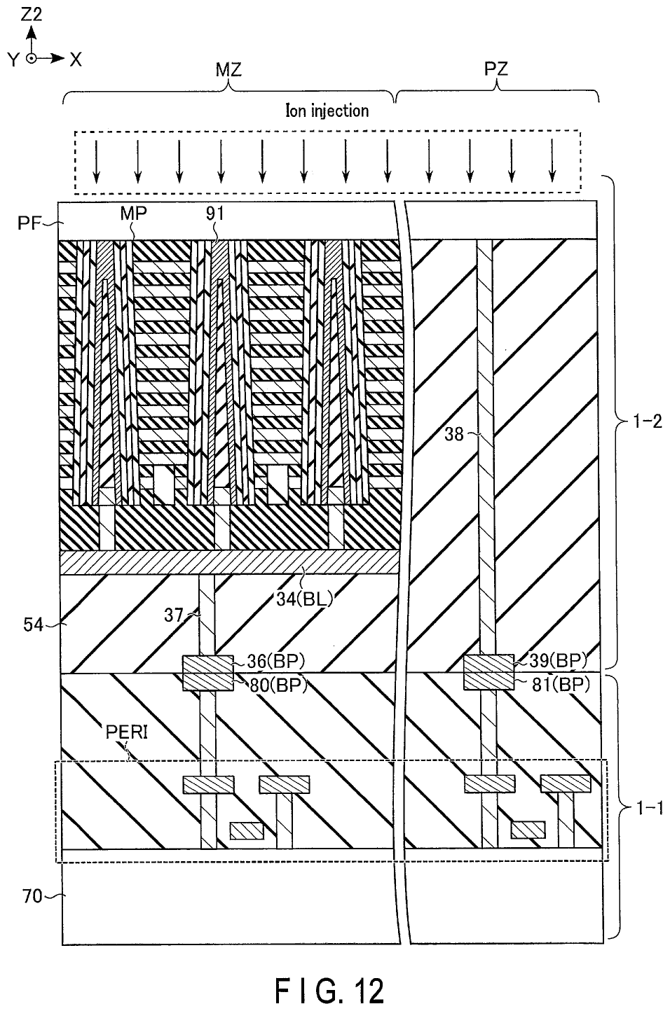

Then, as illustrated in FIG. 12, ion injection into the semiconductor film 91 is implemented (S6). In particular, first, a protective film PF is formed on the first surface of the memory chip 1-2 where the first surface of the semiconductor film 91 is exposed. The protective film PF may be formed by using tetraethyl orthosilicate (TEOS). Next, the first end of the semiconductor film 91 is doped with phosphorus through the protective film PF by the ion injection toward the first surface of the protective film PF.

Next, with laser annealing, an activation process is implemented upon the phosphorus with which the first end of the semiconductor film 91 is doped (S7).

Then, the protective film PF is removed.

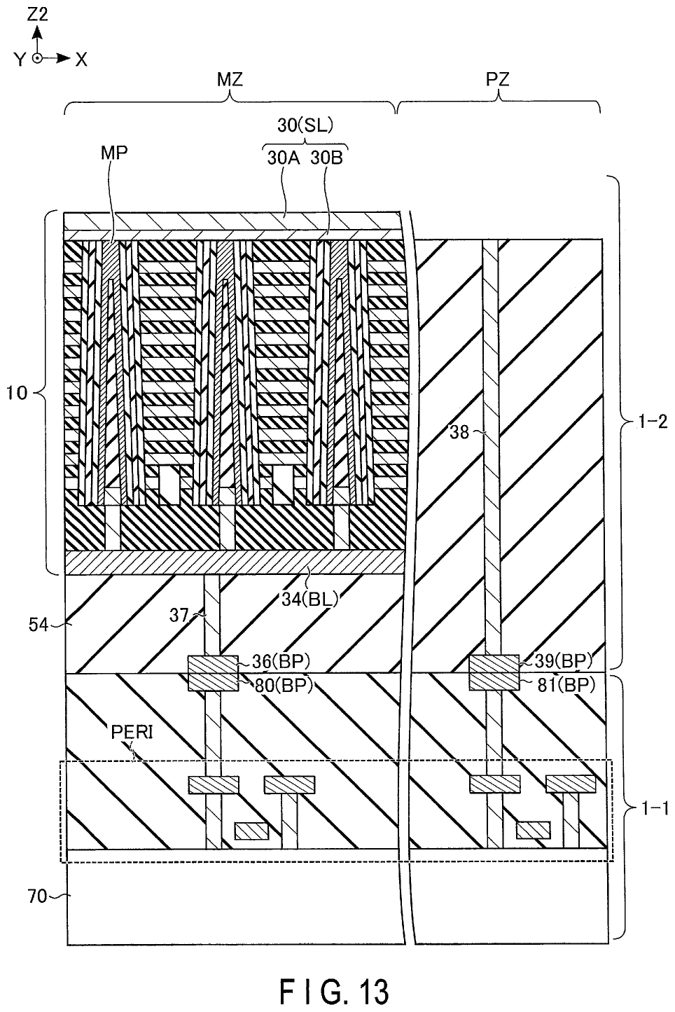

Thereafter, as illustrated in FIG. 13, a conductive layer 30 is formed to function as a source line SL (S8). In particular, a conductive layer 30B is formed on the first surface of the memory chip 1-2 in the region including a memory cell array 10. Next, a conductive layer 30A is formed on the first surface of the conductive layer 30B. Finally, an electrode pad PD and an insulating layer 55 are formed.

The above described manufacturing steps are mere examples. Other steps may be inserted between the manufacturing steps, and the order of manufacturing steps may be changed.

### 1.3 Effects of Present Embodiment

According to the present embodiment, a reduction in yield of the semiconductor memory device 1 can be suppressed. The effects of the present embodiment will be discussed below.

According to the present embodiment, in the manufacturing process of the semiconductor memory device 1, the circuit chip 1-1 and memory chip 1-2 are adhered to each other, and thereafter the semiconductor substrate 100 of the memory chip 1-2 is removed. Then, through the planarizing process using a planarization film FF, the first surface of the memory chip 1-2 is planarized, and the first surface of the semiconductor film 91 of the memory pillar MP is exposed on the first surface of the memory chip 1-2. Thereafter, a conductive layer 30 is formed on the exposed first surface of the semiconductor film 91.

That is, according to the present embodiment, the conductive layer 30 is formed on the first surface of the memory chip 1-2, which has been subjected to the planarizing process. With this, the semiconductor memory device 1 according to the present embodiment can suppress a reduction in the coverage characteristic of a source line in the manufacturing process, in comparison with a configuration in which a source line is formed using amorphous silicon. As a result, a reduction in reliability of products can be suppressed. Consequently, a reduction in yield of the semiconductor memory device 1 can be suppressed.

In particular, when a source line is formed with amorphous silicon, the source line is deposited to cover the first end of the channel exposed on the first surface of the memory chip. That is, after the circuit chip and memory chip are adhered to each other, the semiconductor substrate of the memory chip is removed so that the first end of the insulating film of the memory pillar will be exposed. Then, the exposed first end of the insulating film of the memory pillar is removed so that the first end of the channel of the memory pillar will be exposed.

Thereafter, a silicon layer is deposited on the first surface of the memory chip to cover the exposed first end of the channel of the memory pillar. This silicon layer is constituted by amorphous silicon doped with phosphorous. Next, the amorphous silicon in the silicon layer is crystallized, for example through laser annealing so that the silicon layer will become part of a source line. The amorphous silicon, which is formed to cover the first end of the channel of the memory pillar, tends to have a coverage characteristic that is degraded in comparison with a silicon layer formed on a planarized surface.

According to the present embodiment, the planarizing process brings the first surface of the semiconductor film 91 and the first surface of the insulating layer 50 to approximately the same height. In other words, the source line SL can be formed on a flat surface. This can suppress a reduction in the coverage characteristic.

According to the present embodiment, the first end of the semiconductor film 91 exposed on the first surface of the memory chip 1-2 is doped with phosphorous through ion injection before the conductive layer 30 is formed. Thus, in the semiconductor memory device 1 according to the present embodiment, generation of voids can be suppressed during annealing, in comparison to the formation of a source line using amorphous silicon. This can also suppress a reduction in the yield of the semiconductor memory device 1.

In particular, when forming a source line with amorphous silicon, phosphorous is diffused through laser annealing at the same step as the crystallization of amorphous silicon, thereby accomplishing doping in the channel. There is a possibility, however, that voids may be generated in the silicon layer during the laser annealing for amorphous silicon.

According to the present embodiment, phosphorous is introduced through ion injection to dope the semiconductor film 91 of the memory pillar MP, and laser annealing is adopted to activate the phosphorous in the semiconductor film 91 containing polysilicon, instead of for crystallization of amorphous silicon. As a result, it is possible to suppress the generation of voids due to laser annealing of amorphous silicon.

In addition, according to the present embodiment, containment of amorphous silicon in the source line can be suppressed. As a result, degradation of the performance of the semiconductor memory device can be suppressed due to amorphous silicon remaining in the silicon layer. This can also suppress a reduction in the yield of the semiconductor memory device 1.

In particular, in the formation of a source line with amorphous silicon, it is difficult to form the silicon layer to have a flat first surface with respect to the semiconductor substrate, as mentioned earlier. This makes it difficult to uniformly crystallize the amorphous silicon in the silicon layer through laser annealing. The amorphous silicon remaining in the silicon layer tends to lower the performance of the semiconductor memory device.

According to the present embodiment, the source line is formed of a metal material, which means that silicon is not contained in the source line. Thus, containment of amorphous silicon in the source line can be suppressed, and degradation of the performance of the semiconductor memory device can be suppressed.

Furthermore, according to the present embodiment, because of the phosphorous introduced into the semiconductor film 91 through ion injection, the phosphorous doping can reach a deeper area of the semiconductor film 91 in comparison to the phosphorous doping using amorphous silicon. This will also suppress the degradation in the performance of the semiconductor memory device 1 according to the present embodiment.

In particular, when diffusion is adopted, the depth from the first end of the channel to the channel of the select transistor may be greater than the depth of the channel that the phosphorous doping can reach through laser annealing. As a result, the phosphorus concentration may not attain a sufficient level in the channel of the select transistor. In such a semiconductor memory device, a sufficient GIDL current cannot be generated during an erase operation. This may increase the time required for the processing of the erase operation.

According to the present embodiment, phosphorous can be more reliably introduced for doping up to the channel of the select transistor, in comparison to diffusion doping. Thus, a sufficient GIDL current can be generated according to the present embodiment. As a result, an increase in the processing time for an erase operation can be suppressed, and degradation in the processing capacity of the semiconductor memory device 1 can also be suppressed.

According to the present embodiment, the first end of the semiconductor film 91, which is formed with an n-type semiconductor containing phosphorous, is in contact with the second surface of the conductive layer 30, which is formed of a metal material. This establishes an ohmic contact between the conductive layer 30 and semiconductor film 91, which can suppress an increase in resistance between the source line SL and channel.

### 2. Modification Examples

The above embodiment can be modified in various manners.

Modification examples of the semiconductor memory device will be explained below. The configuration and manufacturing process of the semiconductor memory device according to the modification examples will be explained below, focusing mainly on differences with respect to the semiconductor memory device 1 of the embodiment. The same effects can be produced by the semiconductor memory device according to the modification examples.

### 2.1 Modification Example

In the above embodiment, the conductive layer 31 is determined as the closest one to the conductive layer 30 among the conductive layers included between the conductive layers 30 and 34 in the memory cell array 10, but this is not a limitation. The memory cell array 10 may include additional conductive layers between the conductive layers 30 and 31. The configuration and manufacturing method of the semiconductor memory device 1 according to the first modification example will be explained below, focusing mainly on differences with respect to the semiconductor memory device 1 according to the embodiment.

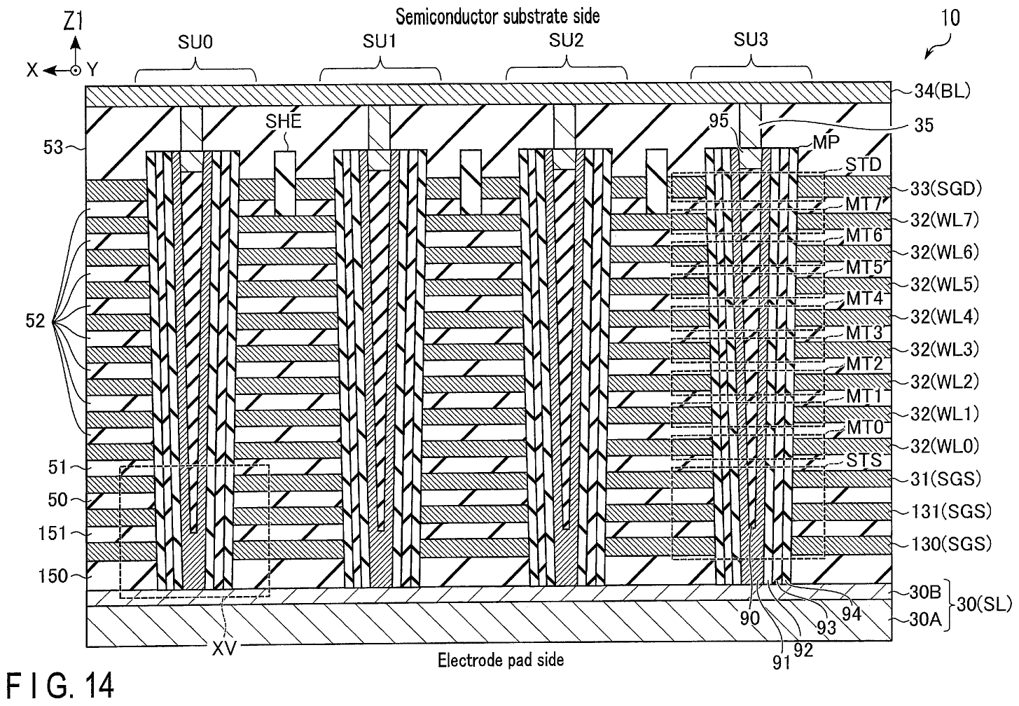

The configuration of the semiconductor memory device 1 according to the first modification example will be explained with reference to FIG. 14, which shows a cross-sectional view of a memory cell array of the semiconductor memory device according to the first modification example.

In the cross-sectional view of FIG. 14, conductive layers 130 and 131 and insulating layers 150 and 151 are included between the conductive layers 30 and 31. In particular, the insulating layer 150, conductive layer 130, insulating layer 151, conductive layer 131, and insulating layer 50 are stacked on the second surface of the conductive layer 30 in this order in the Z1 direction. The conductive layers 130 and 131 may be respectively formed into a plate expanding along the XY plane. In a similar manner to the conductive layer 31, the conductive layers 130 and 131 serve as a select gate line SGS, and may contain tungsten.

In such a configuration of the memory pillar MP, the intersecting portion of the conductive layers 130, 131, and 31 and the memory pillar MP functions as a select transistor STS.

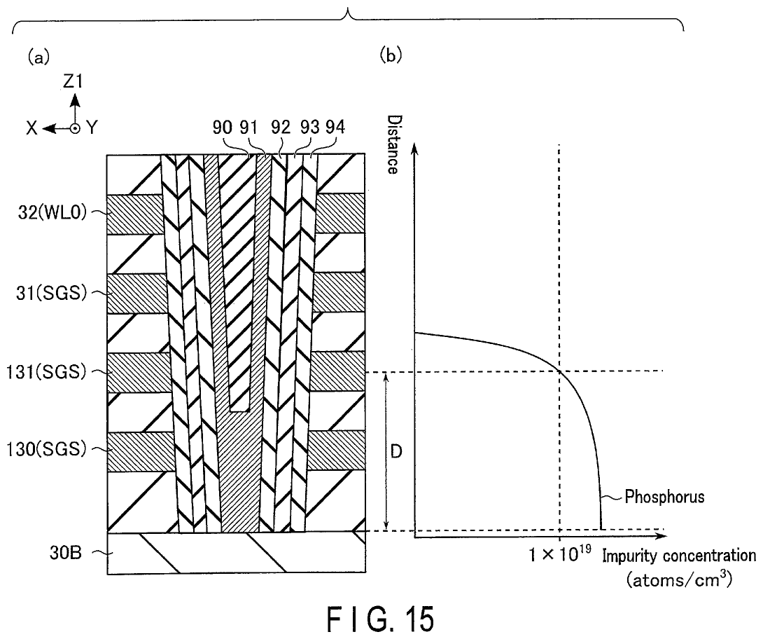

Next, the distribution of impurity concentration in the semiconductor film 91 of the memory pillar MP according to the first modification example will be explained with reference to FIG. 15, which is a conceptual diagram showing a distribution of impurity concentration in the semiconductor film of a memory pillar in the semiconductor memory device according to the first modification example. An enlarged view of the region XV enclosed by the dashed line in FIG. 14 is shown in (a) of FIG. 15, and the distribution of the concentration of impurities contained in the semiconductor film 91 in the region shown in (a) of FIG. 15 is indicated in (b) of FIG. 15.

According to the first modification example, the distance D for phosphorous doping is shorter than the distance from the second surface of the conductive layer 30 to the second surface of the conductive layer 31, and longer than the distance from the second surface of the conductive layer 30 to the first surface of the conductive layer 130. That is, the semiconductor film 91 is formed to include, in the channel of the select transistor STS, an electrode pad PD side portion phosphorous-doped at a concentration of 1×10¹⁹ atoms/cm³ or higher, and a semiconductor substrate 70 side portion phosphorous-doped at a concentration lower than 1×10¹⁹ atoms/cm³.

In the example of FIG. 15, the distance D for phosphorous doping is shorter than the distance from the second surface of the conductive layer 30 to the second surface of the conductive layer 131 and longer than the distance from the second surface of the conductive layer 30 to the first surface of the conductive layer 131. That is, the phosphorus concentration in the channel at approximately the same height as the conductive layer 130 is 1×10¹⁹ atoms/cm³ or higher, while the channel at approximately the same height as the conductive layer 131 includes an electrode pad PD side portion having a phosphorus concentration of 1×10¹⁹ atoms/cm³ or higher and a semiconductor substrate 70 side portion having a phosphorus concentration lower than 1×10¹⁹ atoms/cm³. The phosphorus concentration of the channel at approximately the same height as the conductive layer 31 is lower than 1×10¹⁹ atoms/cm³.

With such a configuration, the channel of the select transistor STS includes a portion having a phosphorus concentration of 1×10¹⁹ atoms/cm³ or higher. As a result, the select transistor STS can generate a GIDL current in the same manner as in the embodiment.

Furthermore, the channel of the select transistor STS includes a portion having a phosphorus concentration lower than 1×10¹⁹ atoms/cm³. As a result, the select transistor STS can function as a switch element in various operations in the same manner as in the embodiment.

In the above first modification example, the conductive layers 130 and 131 arranged between the conductive layers 30 and 31 serve as a select gate line SGS, which is not a limitation. The conductive layers 130 and 131 may not be used as a select gate line SGS. That is, the intersecting portion of the memory pillar MP and the conductive layers 130 and 131 does not necessarily have to be included in a select transistor STS, nor does it have to have a switch element function or a GIDL current generation function.

According to the first modification example, two conductive layers 130 and 131 are included between the conductive layers 30 and 31, which is not a limitation. A single conductive layer may be included between the conductive layers 30 and 31, or three or more conductive layers may be included. If this is the case, the intersecting portion of the memory pillar MP and the single conductive layer between the conductive layers 30 and 31, or of the memory pillar MP and the three or more conductive layers, may be included, or not included, in the select transistor STS. If a plurality of conductive layers are included between the conductive layers 30 and 31, the intersecting portion of the memory pillar MP and some of the conductive layers on the semiconductor substrate 70 side of the conductive layers may be included in the select transistor STS, and the intersecting portion of the memory pillar MP and the remaining conductive layers on the electrode pad PD side may not be included in the select transistor STS.

The method of manufacturing the semiconductor memory device 1 according to the first modification example is substantially the same as the method of manufacturing the semiconductor memory device 1 according to the embodiment, and therefore the explanation is omitted.

The above configuration and manufacturing method can achieve effects equivalent to those of the embodiment.

### 2.2 Modification Example 2

According to the embodiment and the first modification example, the conductive layer 30 is formed of a metal material, which is not a limitation. The conductive layer 30 may include a layer containing polysilicon in place of the metal material. The configuration and manufacturing method of the semiconductor memory device 1 according to the second modification example will be explained below, focusing mainly on differences with respect to the semiconductor memory device 1 according to the embodiment.

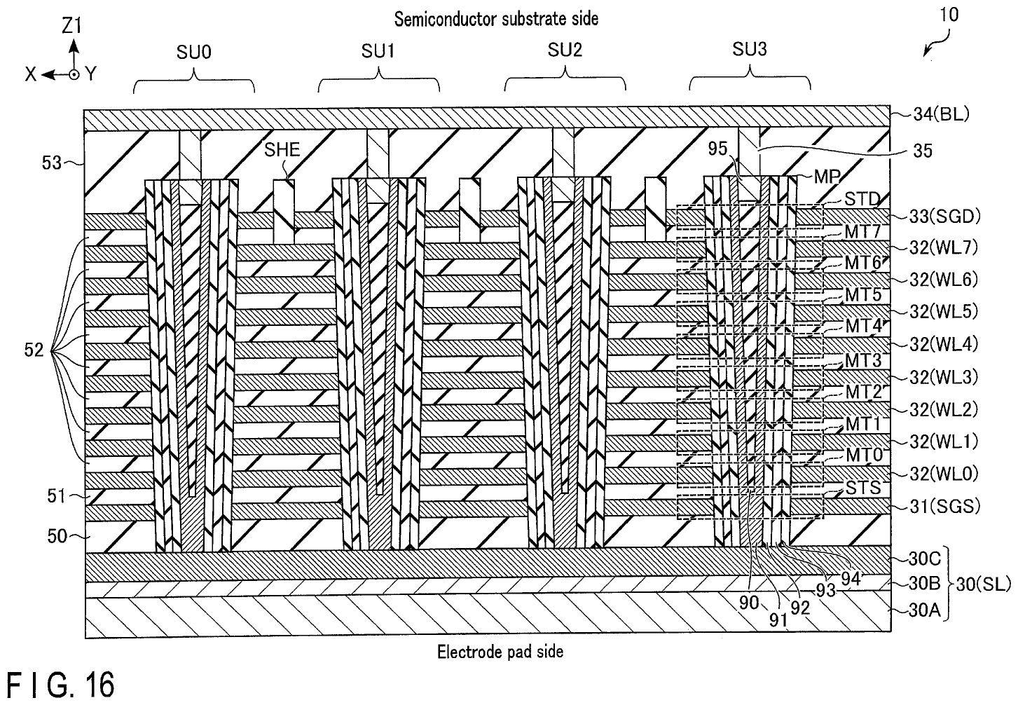

The configuration of the semiconductor memory device 1 according to the second modification example will be explained with reference to FIG. 16, which shows a cross-sectional view of a memory cell array in the semiconductor memory device according to the second modification example.

In the cross-sectional view of FIG. 16, the conductive layer 30 of the memory cell array 10 contains a conductive layer 30C, in addition to the conductive layers 30A and 30B. The conductive layer 30C is stacked on the second surface of the conductive layer 30B. An insulating layer 50 is stacked on the second surface of the conductive layer 30C. The conductive layer 30C is formed of an n-type semiconductor. The n-type semiconductor is polysilicon containing phosphorous as an impurity at the concentration of 1×10¹⁹ atoms/cm³ or higher. In the following explanation, the conductive layer 30C contains phosphorous as an impurity, which is not a limitation. The conductive layer 30C may contain arsenic as an impurity in place of phosphorous.

Next, the method of manufacturing the semiconductor memory device 1 according to the second modification example will be explained below, focusing mainly on differences with respect to the method of manufacturing the semiconductor memory device 1 according to the embodiment.

First, the same operations as the ones at steps S0 to S5 in the method of manufacturing the semiconductor memory device 1 according to the embodiment are conducted.

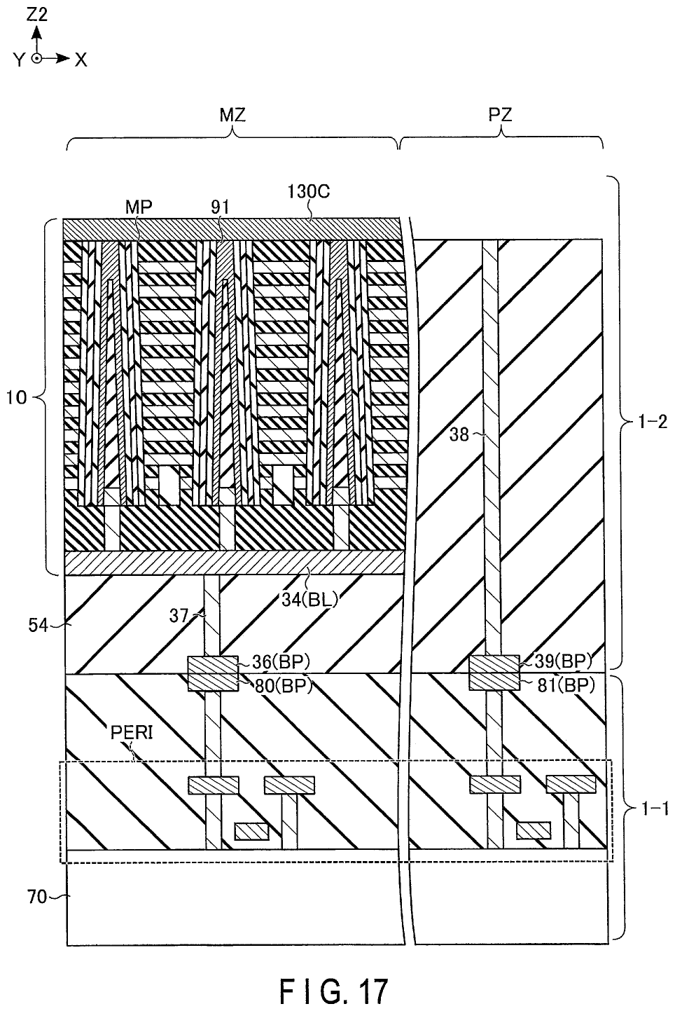

Then, as illustrated in FIG. 17, a polysilicon layer 130C is formed on the first surface of the memory chip 1-2, which has been subjected to the planarizing process. For instance, the polysilicon layer 130C may be formed of polysilicon containing phosphorous at the concentration of 1×10¹⁹ atoms/cm³ or higher. This is not a limitation, however, and the phosphorus concentration of the polysilicon layer 130C may be lower than 1×10¹⁹ atoms/cm³, or the polysilicon layer 130C may not be doped with phosphorous.

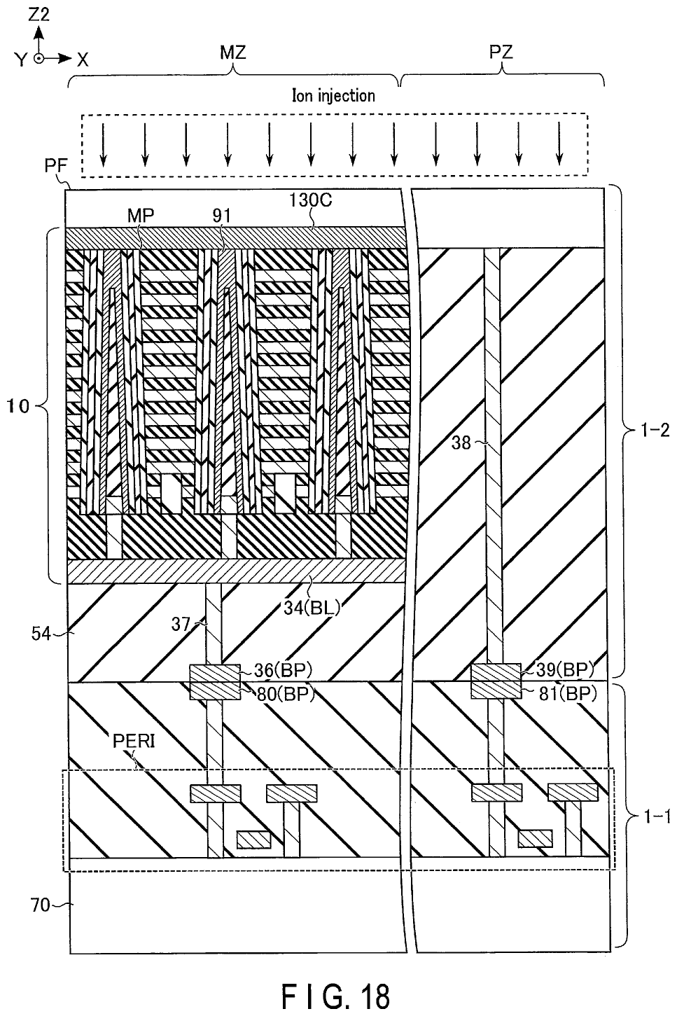

Then, ion injection is conducted upon the semiconductor film 91 in the same manner as in the operation at step S6 according to the embodiment. In particular, a protective film PF is formed to cover the first surface of the polysilicon layer 130C, the first surface of the insulating layer 54, and the first surface of the conductive layer 38. Then, as illustrated in FIG. 18, ion injection is conducted toward the first surface of the formed protective film PF. Through this operation, the polysilicon layer 130C and semiconductor film 91 are doped with phosphorous. As a result, the polysilicon layer 130C becomes a conductive layer 30C.

With the above configuration and manufacturing method, effects equivalent to the embodiment and the first modification example can be attained.

Furthermore, according to the second modification example, a conductive layer 30C of an n-type semiconductor is stacked on the second surface of the conductive layer 30B formed of a metal material. The conductive layer 30C is in contact with the n-type semiconductor portion of the semiconductor film 91. The conductive layer 30C and channel establish an ohmic contact with the conductive layers 30A and 30B in the semiconductor memory device 1. This can suppress an increase in resistance between the source line SL and channel.

### 2.3 Modification Example 3

In the above embodiment, first modification example, and second modification example, the first end of the core member 90 is positioned on the semiconductor substrate 70 side with respect to the conductive layer 30, which is not a limitation. The core member 90 may penetrate the conductive layers 31 to 33 and insulating layers 50 to 52. The configuration and manufacturing method of the semiconductor memory device 1 according to the third modification example will be explained below, focusing mainly on differences with respect to the configuration and manufacturing method of the semiconductor memory device 1 according to the embodiment.

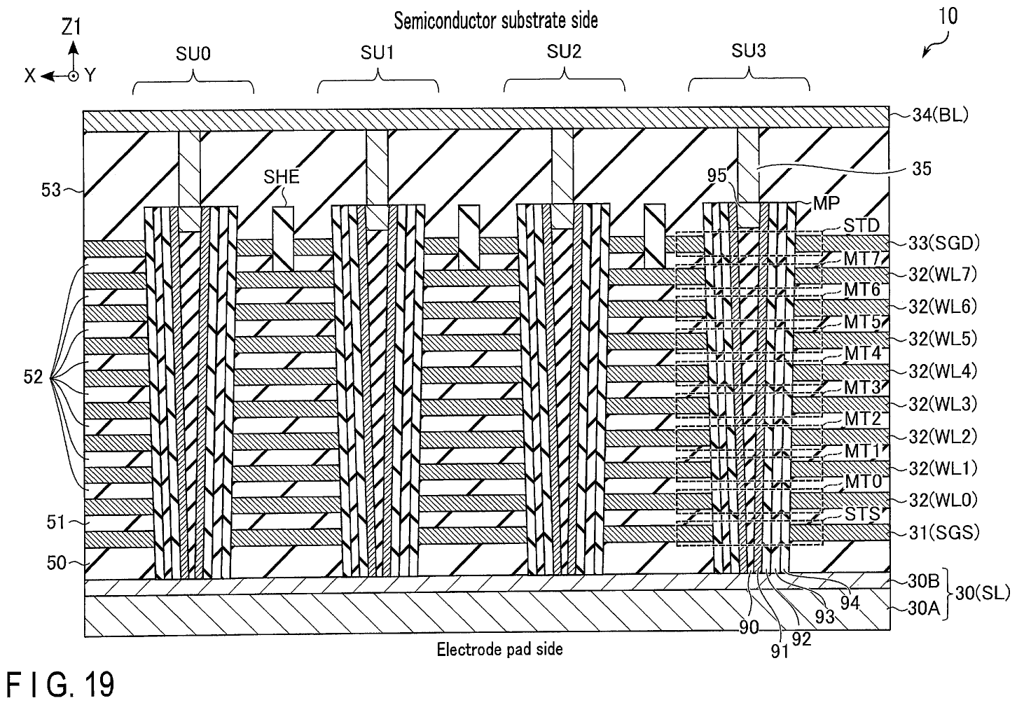

The configuration of the semiconductor memory device 1 according to the third modification example will be explained with reference to FIG. 19, which shows a cross-sectional view of a semiconductor memory device according to the third modification example.

In the cross-sectional view of FIG. 19, the first end of the core member 90 is included at approximately the same height as the first end of the semiconductor film 91, the first end of the tunnel insulating film 92, the first end of the charge storage film 93, and the first end of the block insulating film 94, and is in contact with the second surface of the conductive layer 30. That is, in the same manner as the semiconductor film 91, tunnel insulating film 92, charge storage film 93, and block insulating film 94, the core member 90 according to the third modification example penetrates the conductive layers 31 to 33 and insulating layers 50 to 52.

The method of manufacturing the semiconductor memory device 1 according to the third modification example is substantially the same as the method of manufacturing the semiconductor memory device 1 according to the embodiment, and therefore the explanation is omitted.

With the above configuration and manufacturing method, effects equivalent to the embodiment, first modification example, and second modification example can be attained.

### 3. Other Embodiments

The embodiments of the present invention have been explained. These are presented merely as examples and are not intended to restrict the scope of the invention. These embodiments may be realized in various other forms, and various omissions, replacements, and changes can be made without departing from the gist of the invention. Such embodiments and modifications are included in the scope and gist of the invention, and are included in the scope of the invention described in the claims and its equivalents.

1. A semiconductor memory device comprising:
a substrate, a first conductive layer, and a second conductive layer arranged in this order in a first direction and separated from each other;
a first semiconductor film extending in the first direction, intersecting the first conductive layer, and being in contact with the second conductive layer; and
a first charge storage film arranged between the first semiconductor film and the first conductive layer, and being in contact with the second conductive layer,
wherein the first semiconductor film includes a first portion formed of an n-type semiconductor at approximately a same height as the first conductive layer.

2. The device of claim 1, the device further comprising:
a third conductive layer arranged in an area between the substrate and the first conductive layer in the first direction, separated from the substrate and from the first conductive layer, and intersecting the first semiconductor film and the first charge storage film,
wherein the first semiconductor film, at approximately a same height as the third conductive layer, has an impurity concentration lower than an impurity concentration of the first portion.

3. The device of claim 1, wherein
the first portion includes phosphorous as an impurity.

4. The device of claim 3, wherein
a phosphorus concentration in the first portion is 1×10¹⁹ atoms/cm³ or higher.

5. The device of claim 1, wherein
the second conductive layer includes a metal material.

6. The device of claim 5, the device further comprising:
a first insulating layer arranged between the first conductive layer and the second conductive layer in such a manner as to intersect the first semiconductor film and the first charge storage film, the first insulating layer being in contact with the second conductive layer.

7. The device of claim 1, the device further comprising:
a fourth conductive layer arranged on a top surface of the second conductive layer,
wherein the second conductive layer includes an re-type semiconductor, and
the fourth conductive layer includes a metal material.

8. The device of claim 7, wherein
the n-type semiconductor included in the second conductive layer includes phosphorous as an impurity.

9. The device of claim 1, wherein
the second conductive layer is a source line.

10. The device of claim 1, the device further comprising:
a second semiconductor film extending in the first direction, intersecting the first conductive layer, and being in contact with the second conductive layer; and
a second charge storage film arranged between the second semiconductor film and the first conductive layer, and being in contact with the second conductive layer,
wherein the second semiconductor film includes a second portion formed of an n-type semiconductor at approximately a same height as the first conductive layer, and
the first portion has approximately a same impurity concentration as an impurity concentration of the second portion.

11. The device of claim 1, the device further comprising:
a fifth conductive layer arranged between the substrate and the first conductive layer and electrically coupled to the first semiconductor film,
wherein the fifth conductive layer is a bit line.

12. The device of claim 11, the device further comprising:
a pad arranged above the first conductive layer;
a first contact extending in the first direction between the substrate and the pad and being in contact with the pad;
a second contact extending in the first direction between the substrate and the fifth conductive layer and being in contact with the fifth conductive layer;
a first circuit and a second circuit arranged on the substrate;
a first joint metal coupled to the first circuit and coupled to the first contact; and
a second joint metal coupled to the second circuit and coupled to the second contact,
wherein the first joint metal and the second joint metal are on a same plane orthogonal to the first direction.

13. The device of claim 1, the device further comprising:
a first insulating film extending in the first direction and having a side surface covered by the first semiconductor film,
wherein a top end of the first insulating film is positioned at a height lower than a top end of the first semiconductor film.

14. The device of claim 1, the device further comprising:
a first insulating film extending in the first direction, intersecting the first conductive layer, and having a side surface covered by the first semiconductor film,
wherein the first insulating film is in contact with the second conductive layer.
